(19) United States
(12) Patent Application Publication
(10) Pub. No.: US 2024/0324190 A1
(43) Pub. Date: Sep. 26, 2024

(54) INTEGRATED CIRCUIT DEVICE AND METHOD OF MANUFACTURING THE SAME

(71) Applicant: Samsung Electronics Co., Ltd., Suwon-si (KR)

(72) Inventors: Yunho SONG, Suwon-si (KR); Jooncheol KIM, Suwon-si (KR); Bosu KIM, Suwon-si (KR); Yeji KIM, Suwon-si (KR); Subin SON, Suwon-si (KR); Hyundon YUN, Suwon-si (KR); Namkyeong LEE, Suwon-si (KR)

(73) Assignee: Samsung Electronics Co., Ltd., Suwon-si (KR)

(21) Appl. No.: 18/611,146

(22) Filed: Mar. 20, 2024

(30) Foreign Application Priority Data
Mar. 24, 2023 (KR) 10-2023-0039149
Jun. 21, 2023 (KR) 10-2023-0079813

(51) Int. Cl. H10B 12/00

(52) U.S. Cl. CPC H10B 12/50; H10B 12/482

(57) ABSTRACT

An integrated circuit device includes a substrate including a cell array area and a peripheral circuit area next to the cell array area, an isolation layer defining an activation region of the substrate in the peripheral circuit area, the isolation layer including a first insulation pattern and a second insulation pattern surrounding the first insulation pattern, and a gate structure on the substrate in the peripheral circuit area, wherein the second insulation pattern includes one or more surfaces defining a recess into an upper surface of the substrate in a vertical direction, the vertical direction extending perpendicular to the upper surface of the substrate.

### CROSS-REFERENCE TO RELATED APPLICATIONS

This application is based on and claims priority under 35 U.S.C. § 119 to Korean Patent Application No. 10-2023-0039149, filed on Mar. 24, 2023 in the Korean Intellectual Property Office, and Korean Patent Application No. 10-2023-0079813, filed on Jun. 21, 2023 in the Korean Intellectual Property Office, the disclosure of each of which is incorporated by reference herein in its entirety.

### BACKGROUND

The inventive concepts relate to integrated circuit devices and methods of manufacturing the same, and in particular, to integrated circuit devices including bit lines and methods of manufacturing the same.

In accordance with the downscaling of integrated circuit devices, the size of individual fine circuit patterns for implementing integrated circuit devices is decreasing. In addition, as integrated circuit devices become highly integrated, the line width of bit lines is reducing and processes for forming contacts between bit lines increases are becoming increasingly difficult.

### SUMMARY

Some example embodiments of the inventive concepts provide an integrated circuit device having improved electrical characteristics and reliability.

Some example embodiments of the inventive concepts provide a method of manufacturing an integrated circuit device with low processing difficulty.

According to some example embodiments of the inventive concepts, an integrated circuit device may include a substrate including a cell array area and a peripheral circuit area next to the cell array area, an isolation layer defining an activation region of the substrate in the peripheral circuit area, the isolation layer including a first insulation pattern and a second insulation pattern surrounding the first insulation pattern, and a gate structure disposed on the substrate in the peripheral circuit area, wherein the second insulation pattern includes one or more surfaces defining a recess that is recessed in an upper surface of the substrate in a vertical direction, the vertical direction extending perpendicular to the upper surface of the substrate.

According to some example embodiments of the inventive concepts, an integrated circuit device may include a substrate including a cell array area and a peripheral circuit area next to the cell array area, an isolation layer defining an activation area of the substrate, a peripheral circuit gate structure on the substrate in the peripheral circuit area, a first insulating spacer at least partially covering a sidewall of the peripheral circuit gate structure, and a second insulating spacer at least partially covering a sidewall of the first insulating spacer. A vertical level of an upper surface of the second insulating spacer may be lower than a vertical level of an upper surface of the first insulating spacer.

According to some example embodiments of the inventive concepts, an integrated circuit device may include a substrate including a cell array area and a peripheral circuit area next to the cell array area, an isolation layer defining an activation area of the substrate, a plurality of bit lines extending on the substrate in the cell array area in a first direction that is parallel to an upper surface of the substrate, a plurality of insulating capping structures on separate, respective bit lines of the plurality of bit lines and extending in the first direction, a conductive plug between two adjacent bit lines from among the plurality of bit lines; a landing pad on the conductive plug, and a gate structure on the substrate, in the peripheral circuit area, wherein each of the plurality of insulating capping structures includes a separate sequential stack of a lower capping pattern, a first insulating layer pattern, a second insulating layer pattern, and an upper capping pattern, each separate sequential stack on a separate bit line of the plurality of bit lines. A width of the second insulating layer pattern in a second direction may be less than a width in the second direction of at least one of the lower capping pattern, the first insulating layer pattern, and the upper capping pattern. The second direction may be parallel to the upper surface of the substrate and perpendicular to the first direction.

### BRIEF DESCRIPTION OF THE DRAWINGS

Some example embodiments of the inventive concepts will be more clearly understood from the following detailed description taken in conjunction with the accompanying drawings in which:

FIG. 1 is a plan view of an integrated circuit device according to some example embodiments of the inventive concepts;

FIG. 2A shows cross-sectional views of the integrated circuit device taken along lines A1-A1′ and A2-A2′ of FIG. 1 according to some example embodiments of the inventive concepts;

FIG. 2B is a cross-sectional view of the integrated circuit device taken alone line B-B′ of FIG. 1 according to some example embodiments of the inventive concepts;

FIG. 3 is an enlarged view of part P in FIG. 2A according to some example embodiments of the inventive concepts;

FIG. 4 is an enlarged view of part Q in FIG. 2B according to some example embodiments of the inventive concepts;

FIG. 5 is a cross-sectional view of an integrated circuit device according to some example embodiments of the inventive concepts, taken along line B-B′ of FIG. 1; and

FIGS. 6A, 6B, 7A, 7B, 8A, 8B, 9, 10A, 10B, 11A, 11B, 12, 13, 14, 15, 16, 17, 18, 19A, 19B, 20A, and 20B are cross-sectional views describing a method of manufacturing an integrated circuit device, according to some example embodiments of the inventive concepts, according to a process order. In detail, FIGS. 6A, 7A, 8A, 10A, 11A, 12, 13, 14, 15, 16, 17, 18, 19A, and 20A are cross-sectional views corresponding to cross-sections taken along lines A1-A1′ and A2-A2′ of FIG. 1, and FIGS. 6B, 7B, 8B, 9, 10B, 11B, 19B, and 20B are cross-sectional views corresponding to a cross-section taken along line B-B′ of FIG. 1.

### DETAILED DESCRIPTION

Hereinafter, some example embodiments of the inventive concepts will be described in detail with reference to accompanying drawings.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, an element that is “on” another element may be above, beneath, or horizontally next to (e.g., horizontally adjacent to) the other element and is not necessarily above an upper side of the other element based on a gravitational direction.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

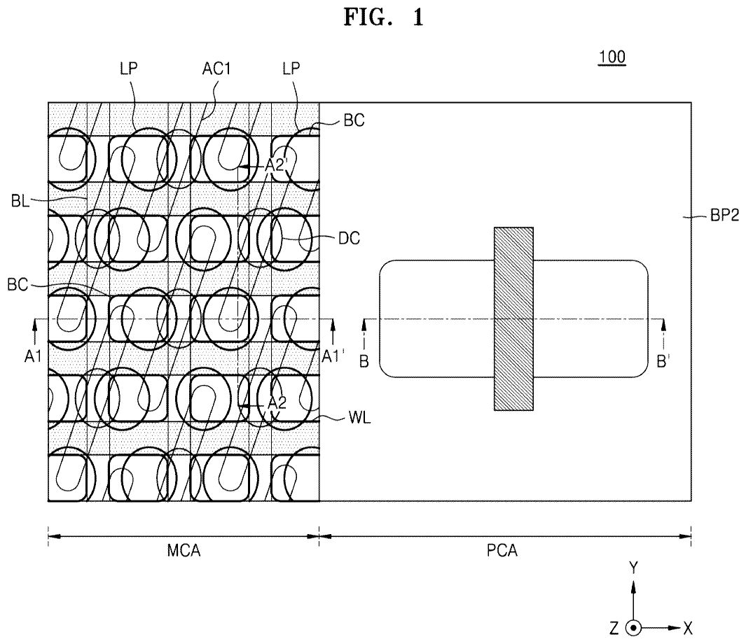

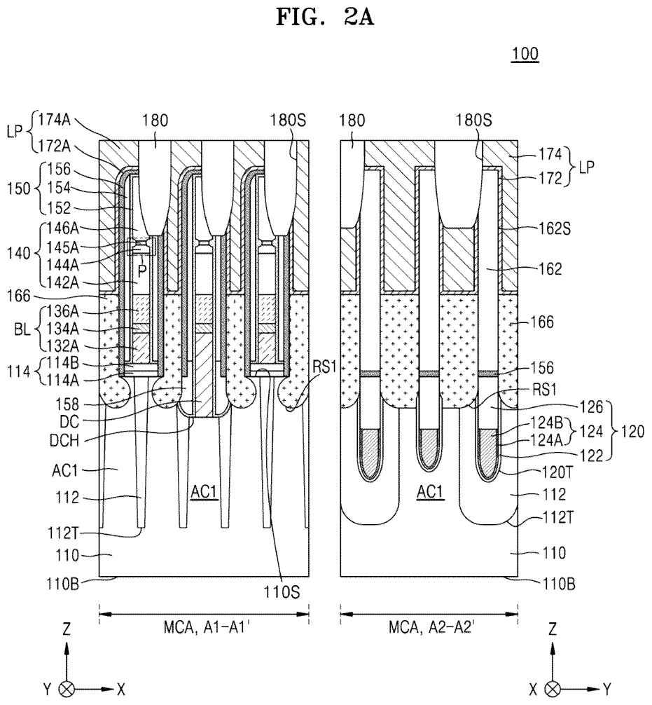

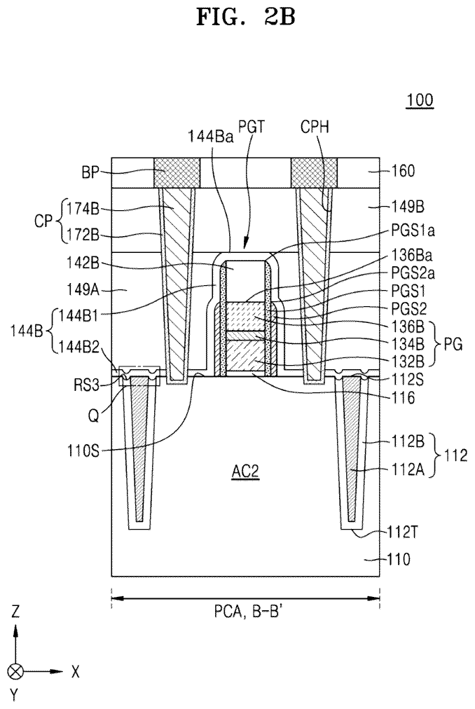

FIG. 1 is a cross-sectional view of an integrated circuit device 100 according to some example embodiments of the inventive concepts. FIG. 2A shows cross-sectional views of the integrated circuit device taken along lines A1-A1′ and A2-A2′ of FIG. 1 according to some example embodiments of the inventive concepts. FIG. 2B is a cross-sectional view of the integrated circuit device taken along line B-B′ of FIG. 1 according to some example embodiments of the inventive concepts.

Referring to FIGS. 1 to 2B, the integrated circuit device 100 may include a substrate 110 including a cell array area MCA and a peripheral circuit area PCA. The peripheral circuit area PCA may be next to (e.g., adjacent to, including directly adjacent to, in at least the first direction X as shown in at least FIG. 1) the cell array area MCA. In the substrate 110, isolation trenches 112T are formed, and isolation layers 112 may be formed in the isolation trenches 112T. A plurality of first activation areas AC1 are defined in the substrate 110 in the cell array area MCA and a second activation area AC2 may be defined in the substrate 110 in the peripheral circuit area PCA by the isolation layer 112.

In the peripheral circuit area PCA, the isolation layer 112 may include a first insulation pattern 112A and a second insulation pattern 112B surrounding the first insulation pattern 112A (e.g., surrounding and/or overlapping in the horizontal plane, including the first direction X and the second direction Y, surrounding and/or overlapping a bottom of the first insulation pattern 112A in the third direction Z, etc.). A vertical level of a lower surface of the first insulation pattern 112A may be higher than that of a lower surface of the second insulation pattern 112B. The first insulation pattern 112A may be spaced apart from the second activation area AC2 of the substrate 110 with the second insulation pattern 112B therebetween. Although not shown in the drawings, the isolation layer 112 may include the first insulation pattern 112A and the second insulation pattern 112B in the cell array area MCA. This may vary depending on the design of the integrated circuit device to be manufactured. The second insulation pattern 112B may include a material having etch selectivity with respect to the first insulation pattern 112A. For example, the first insulation pattern 112A may include silicon nitride, and the second insulation pattern 112B may include silicon oxide.

The plurality of first activation areas AC1 may each be arranged to have a longer shaft in a diagonal direction with respect to a first direction X and a second direction Y. A plurality of word lines WL may extend in parallel with each other along the first direction X across the plurality of first activation areas AC1. A plurality of bit lines BL may extend in parallel with one another in the second direction (Y) on the plurality of word lines WL. The plurality of bit lines BL may be connected to the plurality of first activation areas AC1 via direct contacts DC.

In the specification, the first direction X may be defined as a direction that is parallel to the upper surface 110S of the substrate 110, the second direction Y may be defined as a direction that is parallel to the upper surface 110S of the substrate 110 and crosses the first direction X, and a third direction Z may be defined as a direction perpendicular to the upper surface 110S of the substrate 110. As described herein, a “level” or “vertical level” of an element of the integrated circuit device (e.g., a structure, surface, or the like in the integrated circuit device) may be understood to refer to a distance of the element from a reference location in the integrated circuit device (e.g., a bottom surface 110B of the substrate 110, an upper surface 110S of the substrate 110, etc.) in the third direction Z. For example, when a “level” of an element of the integrated circuit device is described to be higher than that of another element of the integrated circuit device, it will be understood that the element is further from a reference location (e.g., a bottom surface 110B of the substrate 110, an upper surface 110S of the substrate 110, etc.) in the third direction Z than the other element. In another example, when a “level” of an element of the integrated circuit device is described to be lower than that of another element of the integrated circuit device, it will be understood that the element is closer to a reference location (e.g., a bottom surface 110B of the substrate 110, an upper surface 110S of the substrate 110, etc.) in the third direction Z than the other element.

A plurality of buried contacts BC may be formed between two adjacent bit lines BL from among the plurality of bit lines BL. A plurality of buried contacts BC may be arranged in a row along the first direction X and the second direction Y. A plurality of landing pads LP may be formed on the plurality of buried contacts BC. The plurality of buried contacts BC and the plurality of landing pads LP may connect lower electrodes (not shown) of capacitors formed on the plurality of bit lines BL to the first activation areas AC1. Each of the plurality of landing pads LP may partially overlap each of the buried contacts BC.

The substrate 110 may include silicon, e.g., single-crystalline silicon, polycrystalline silicon, or amorphous silicon. In some example embodiments, the substrate 110 may include at least one selected from Ge, SiGe, SiC, GaAs, InAs, and InP. In some example embodiments, the substrate 110 may include a conductive region, for example, a well doped with impurities or a structure doped with impurities.

In the cell array area MCA, a plurality of word line trenches 120T extending in the first direction X are formed in the substrate 110, and a plurality of embedded gate structures 120 may be disposed in the plurality of word line trenches 120T. Each of the plurality of embedded gate structures 120 may include a gate dielectric layer 122, an embedded gate electrode 124, and a capping insulating layer 126. The embedded gate electrode 124 included in each of the plurality of embedded gate structures 120 may correspond to each of the plurality of word lines WL shown in FIG. 1. The gate dielectric layer 122 may include a silicon oxide layer, a silicon nitride layer, a silicon oxynitride layer, an oxide/nitride/oxide (ONO) layer, or a high-k dielectric layer having a greater dielectric constant than that of the silicon oxide layer. The gate electrode 124 may include a work function adjusting layer 124A that is conformally arranged on a lower inner wall in each of the plurality of word line trenches 120T, and an embedded conductive layer 124B filling the lower inner wall in each of the plurality of word line trenches 120T. For example, the work function adjusting layer 124A may include metal, metal nitride, or metal carbide such as Ti, TiN, TiAlN, TiAlC, TiAlCN, TiSiCN, Ta, TaN, TaAlN, TaAlCN, TaSiCN, etc., and the embedded conductive layer 124B may include at least one selected from W, WN, TIN, TaN, and doped polysilicon. The capping insulating layer 126 may include a silicon oxide layer, a silicon nitride layer, a silicon oxynitride layer, or any combination thereof.

In the cell array area MCA, a buffer layer 114 may be formed on the substrate 110. The buffer layer 114 may include a first insulating layer 114A and a second insulating layer 114B. Each of the first insulating layer 114A and the second insulating layer 114B may include an oxide layer, a nitride layer, or any combination thereof.

A plurality of direct contacts DC may be formed in a plurality of direct contact holes DCH in the substrate 110. The plurality of direct contacts DC may be connected to the plurality of first activation areas AC1. The plurality of direct contacts DC may include doped polysilicon. For example, the plurality of direct contacts DC may include polysilicon including a relatively high concentration of n-type impurities such as phosphor (P), arsenic (As), bismuth (Bi), and antimony (Sb).

The plurality of bit lines BL may extend along the second direction Y on the substrate 110 and the plurality of direct contacts DC. Each of the plurality of bit lines BL may be connected to the first activation area AC1 via the direct contact DC. Each of the plurality of bit lines BL may include a lower conductive pattern 132A, an intermediate conductive pattern 134A, and an upper conductive pattern 136A that are sequentially stacked on the substrate 110. The lower conductive pattern 132A may include doped polysilicon. The intermediate conductive pattern 134A and the upper conductive pattern 136A may each include TIN, TiSiN, W, tungsten silicide, or any combination thereof. In some example embodiments, the intermediate conductive pattern 134A may include TiN, TiSiN, or any combination thereof, and the upper conductive pattern 136A may include W.

The plurality of bit lines BL may be respectively covered by a plurality of insulating capping structures 140. Each of the plurality of insulating capping structures 140 may include a lower capping pattern 142A, a first insulating layer pattern 144A, a second insulating layer pattern 145A, and an upper capping pattern 146A. The lower capping pattern 142A, the first insulating layer pattern 144A, and the upper capping pattern 146A may include a material having etch selectivity with respect to the second insulation pattern 112B. For example, the lower capping pattern 142A, the first insulating layer pattern 144A, and the upper capping pattern 146A may include silicon nitride. The second insulating layer pattern 145A may include silicon oxynitride. The plurality of insulating capping structures 140 may extend in the second direction Y on the plurality of bit lines BL.

Spacer structures 150 may be disposed on both sidewalls (e.g., opposite sidewalls) of each of the plurality of bit lines BL. The spacer structure 150 may extend in the second direction Y on both sidewalls of the plurality of bit lines BL, and part of the spacer structure 150 may extend into the direct contact hole DCH so as to cover both sidewalls (e.g., opposite sidewalls) of the direct contacts DC.

In some example embodiments, the spacer structure 150 may include a first spacer layer 152, a second spacer layer 154, and a third spacer layer 156. The first spacer layers 152 may be conformally disposed on the sidewalls of the plurality of bit lines BL, the sidewalls of the insulating capping structure 140, and the inner walls of the direct contact holes DCH. The second spacer layer 154 and the third spacer layer 156 may be sequentially disposed on the first spacer layer 152. In some example embodiments, the first and third spacer layers 152 and 156 may include silicon nitride, and the second spacer layer 154 may include silicon oxide. In some example embodiments, the first and third spacer layers 152 and 156 may include silicon nitride, and the second spacer layer 154 may include air or low-k dielectric material. In the specification, the term “air” may denote atmosphere or a space including other gases that may exist during manufacturing processes.

The embedded insulation layer 158 may surround the lower sidewall of the direct contact DC on the first spacer layer 152, and may fill the remaining space of the direct contact hole DCH. The embedded insulation layer 158 may include silicon nitride, silicon oxynitride, silicon oxide, or any combination thereof.

The direct contacts DC may be formed in the direct contact holes DCH formed in the substrate 110, and may extend to a higher level than the upper surface of the substrate 110. For example, the upper surface of the direct contact DC may be at the same level as the upper surface of the lower conductive pattern 132A and may come into contact with the bottom surface of the intermediate conductive pattern 134A. Also, the bottom surface of the direct contact DC may be at a level lower than that of the upper surface 110S of the substrate 110.

A plurality of insulating fences 162 and a plurality of conductive plugs 166 may be arranged in a row between the plurality of bit lines BL in the second direction Y. The plurality of insulating fences 162 may be disposed on the capping insulating layers 126 that are disposed on the plurality of word line trenches 120T and may each have an upper surface that is at the same level as that of the upper surface of the insulating capping structure 140. The plurality of conductive plugs 166 may extend lengthily from first recesses RS1 formed in the substrate 110 in the vertical direction (third direction Z). Both sidewalls (e.g., opposite sidewalls) of each of the plurality of conductive plugs 166 in the second direction Y may be insulated from each other by the plurality of insulating fences 162. The plurality of insulating fences 162 may include a silicon nitride layer. The plurality of conductive plugs 166 may form the plurality of buried contacts BC shown in FIG. 1.

A plurality of metal silicide layers (not shown) and the plurality of landing pads LP may be formed on the plurality of conductive plugs 166. The metal silicide layer and the landing pad LP may be arranged to overlap the conductive plug 166 in the vertical direction. The metal silicide layer may include cobalt silicide, nickel silicide, or manganese silicide. Each of the plurality of landing pads LP may be connected to the conductive plug 166 via the metal silicide layer.

The plurality of landing pads LP may cover the sidewall of the insulating capping structure 140 so as to vertically overlap (e.g., overlap in the third direction Z) some of the plurality of bit lines BL.

The plurality of landing pads LP may each include a conductive barrier layer 172A and a landing pad conductive layer 174A. The conductive barrier layer 172A may include Ti, TiN, or any combination thereof. The landing pad conductive layer 174A may include metal, metal nitride, conductive polysilicon, or any combination thereof. For example, the landing pad conductive layer 174A may include W. The plurality of landing pads LP may have an island-type pattern shape on a plane (e.g., a plane extending in the first and second directions X and Y).

The plurality of landing pads LP may be electrically insulated from one another due to insulating patterns 180 filled in insulating spaces 180S around the plurality of landing pads LP. The insulating pattern 180 may fill the insulating space 180S arranged between the bit line BL and the conductive plug 166 and may cover both sidewalls of the insulating capping structure 140.

In some example embodiments, the insulating pattern 180 may include silicon nitride, silicon oxynitride, silicon oxide, or any combination thereof. In some example embodiments, the insulating pattern 180 may have a dual-layered structure including a first material layer (not shown) and a second material layer (not shown), and the first material layer may include a low-k material such as SiO₂, SiOCH, and/or SiOC and the second material layer may include silicon nitride or silicon oxynitride.

In the peripheral circuit area PCA, a peripheral circuit gate structure PGT may be formed on the second activation area AC2 and thus may be understood to be on the substrate 110 in the peripheral circuit area PCA. The peripheral circuit gate structure PGT may include a gate dielectric layer 116, a peripheral circuit gate electrode PG, and the gate capping pattern 142B sequentially stacked on the second activation area AC2.

The gate dielectric layer 116 may include at least one selected from a silicon oxide layer, a silicon nitride layer, a silicon oxynitride layer, oxide/nitride/oxide (ONO), and a high-k dielectric layer having a dielectric constant that is greater than that of the silicon oxide layer. The peripheral circuit gate electrode PG may include a lower conductive pattern 132B, an intermediate conductive pattern 134B, and an upper conductive pattern 136B. The lower conductive pattern 132B, the intermediate conductive pattern 134B, and the upper conductive pattern 136B may respectively include the same materials as those of the lower conductive pattern 132A, the intermediate conductive pattern 134A, and the upper conductive pattern 136A included in the bit line BL in the cell array area MCA. The gate capping pattern 142B may include a silicon nitride layer.

First insulating spacers PGS1 and second insulating spacers PGS2 may be sequentially disposed on the sidewalls of the peripheral circuit gate structure PGT. Both sidewalls (e.g., opposite sidewalls) of the peripheral circuit gate structure PGT may be covered (e.g., directly contacted and/or overlapped in the first and/or second direction X and/or Y) by the first insulating spacers PGS1. The second insulating spacer PGS2 may at least partially cover (e.g., directly contact and/or overlap in the first and/or second direction X and/or Y) the sidewall of the first insulating spacer PGS1. A vertical level of an uppermost surface PGS2a of the second insulating spacer PGS2 may be lower than that of an uppermost surface PGS1a of the first insulating spacer PGS1. A vertical level of an uppermost surface PGS2a of the second insulating spacer PGS2 may be the same or substantially the same as that of an upper surface 136Ba of the upper conductive pattern 136B. In the specification, the expression “substantially the same” may denote a concept including errors during manufacturing processes. The second insulating spacer PGS2 may include a material having etch selectivity with respect to the first insulation pattern 112A and the first insulating spacer PGS1. For example, the first insulating spacer PGS1 may include silicon nitride, and the second insulating spacer PGS2 may include silicon oxide.

The peripheral circuit gate structure PGT, the first insulating spacer PGS1, and the second insulating spacer PGS2 (e.g., at least portions thereof that are exposed from the substrate 110) may be covered (e.g., directly contacted, isolated, and/or overlapped in the first to third directions X, Y, and Z) by a protective layer 144B. The protective layer 144B may include a first portion 144B1 and a second portion 144B2 extending from the first portion 144B1. The first portion 144B1 may cover (e.g., directly cover) the peripheral circuit gate structure PGT, the first insulating spacers PGS1, and the second insulating spacers PGS2. The second portion 144B2 may extend from the first portion 144B1 onto the upper surface 110S of the substrate 110. The second portion 144B2 may cover (e.g., directly cover) the upper surface 112S of the isolation layer 112. The protective layer 144B may include a silicon nitride layer.

A first interlayer insulating layer 149A may be formed around the gate structure PGT on the protective layer 144B. The first interlayer insulating layer 149A may at least partially cover the protective layer 144B. The first interlayer insulating layer 149A may not cover the uppermost surface 144Ba of the protective layer 144B vertically overlapping the gate structure PGT (e.g., in the third direction Z). The first interlayer insulating layer 149A may include Tonen SilaZene (TOSZ), but is not limited thereto. The gate structure PGT, the protective layer 144B, and the first interlayer insulating layer 149A may be covered by a second interlayer insulating layer 149B. The second interlayer insulating layer 149B may include a silicon nitride layer.

In the peripheral circuit area PCA, a contact plug CP that passes through the second interlayer insulating layer 149B, the first interlayer insulating layer 149A, and the protective layer 144B in the vertical direction and extends to the second activation area AC2 of the substrate 110 may be formed. The contact plug CP may include a conductive barrier layer 172B and a landing pad conductive layer 174B, like the plurality of landing pads LP formed in the cell array area MCA. A metal silicide layer (not shown) may be provided between the second activation area AC2 and the contact plug CP. The metal silicide layer (not shown) may include cobalt silicide, nickel silicide, or manganese silicide.

A third interlayer insulating layer 160 may be disposed on the second interlayer insulating layer 149B. A metal wiring BP that is connected to the contact plug CP after passing through the third interlayer insulating layer 160 may be arranged. The metal wiring BP may be formed in a via shape, but is not limited thereto, that is, may be formed in a line type.

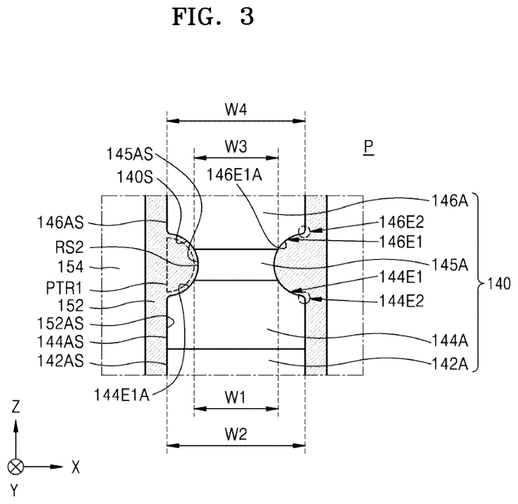

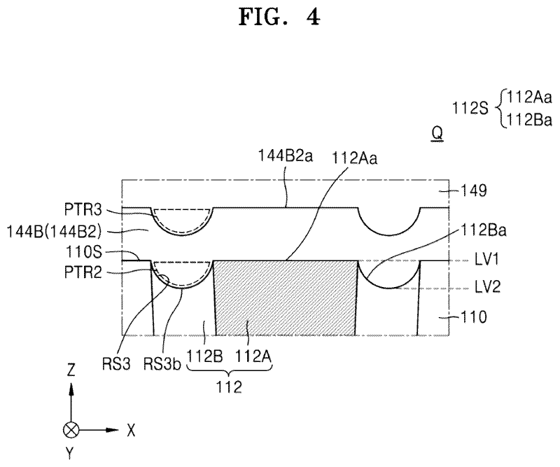

FIG. 3 is an enlarged view of part P in FIG. 2A according to some example embodiments of the inventive concepts. FIG. 4 is an enlarged view of part Q in FIG. 2B according to some example embodiments of the inventive concepts.

Referring to FIG. 3, the insulating capping structure 140 may include (e.g., may define, may include one or more surfaces that define, etc.) a second recess RS2. For example, the insulating capping structure 140 may include one or more surfaces 140S, including for example outer surfaces of portions 144E1 and 144E2, a sidewall 145AS, outer surfaces of portions 146E1 and 146E2, etc., that may define a second recess RS2. In detail, the second recess RS2 may be formed in (e.g., at least partially defined by) the sidewall 145AS of the second insulating layer pattern 145A. Due to the second recess RS2, the second insulating layer pattern 145A may have both sides (e.g., opposite sides, opposite sidewalls 145AS, etc.) that are recessed in a round shape (e.g., concave) in the first direction X.

The first insulating layer pattern 144A may have a first corner portion 144E1 and a second corner portion 144E2 at corners that are adjacent to the second insulating layer pattern 145A and the upper capping pattern 146A. The first corner portion 144E1 may be a portion that is smoothly (e.g., continuously, without discontinuous change in the first direction X with a corresponding change in the third direction Z, etc.) connected to the sidewall 145AS of the second insulating layer pattern 145A due to the second recess RS2. The second corner portion 144E2 may be connected to the first corner portion 144E1. The first corner portion 144E1 of the first insulating layer pattern 144A may have a chamfered shape. The chamfered shape denotes a shape in which the first corner portion 144E1 of the first insulating layer pattern 144A have both sides (e.g., opposite surfaces 144E1A) recessed in the first direction X. The second corner portion 144E2 of the first insulating layer pattern 144A may be round (e.g., may be rounded, may have a round shape, etc.).

The upper capping pattern 146A may have a third corner portion 146E1 and a fourth corner portion 146E2 at corners that are adjacent to the second insulating layer pattern 145A and the first insulating layer pattern 144A. The third corner portion 146E1 may be a portion that is smoothly (e.g., continuously, without discontinuous change in the first direction X with a corresponding change in the third direction Z, etc.) connected to the sidewall 145AS of the second insulating layer pattern 145A due to the second recess RS2. The fourth corner portion 146E2 may be connected to the third corner portion 146E1. The third corner portion 146E1 of the upper capping pattern 146A may have a chamfered shape. The chamfered shape denotes a shape in which the third corner portion 146E1 of the upper capping pattern 146A have both sides (e.g., opposite surfaces 146E1A) recessed in the first direction X. The fourth corner portion 146E2 of the upper capping pattern 146A may have a round surface.

The first insulating layer pattern 144A may include an upper portion and a lower portion under the upper portion, the upper portion horizontally overlapping the first corner portion 144E1. The first insulating layer pattern 144A may have a first width W1 and a second width W2. The first width W1 may be a minimum width of the upper portion of the first insulating layer pattern 144A in the first direction X. The second width W2 may be a width of the lower portion of the first insulating layer pattern 144A in the first direction X and may be a maximum width of the upper portion of the first insulating layer pattern 144A in the first direction X. Due to the second recess RS2 and the first corner portion 144E1, the first width W1 may be less (e.g., smaller) than the second width W2.

The upper capping pattern 146A may include an upper portion and a lower portion under the lower portion, the lower portion horizontally overlapping the third corner portion 146E1. The upper capping pattern 146A may have a third width W3 and a fourth width W4. The third width W3 may be a minimum width of the lower portion of the upper capping pattern 146A in the first direction X. The fourth width W4 may be a width of the upper portion of the upper capping pattern 146A in the first direction X and may be a maximum width of the lower portion of the upper capping pattern 146A in the first direction X. Due to the second recess RS2, the third width W3 may be less (e.g., smaller) than the fourth width W4.

The recess that is recessed in the first direction X may not exist in the portion adjacent to a boundary surface between the lower capping pattern 142A and the first insulating layer pattern 144A. A sidewall 142AS of the lower capping pattern 142A and a sidewall 144AS of the first insulating layer pattern 144A may be aligned parallel to each other (e.g., flush, coplanar, etc.). In detail, the sidewall 142AS of the lower capping pattern 142A and the sidewall 144AS of the first insulating layer pattern 144A may be located on a straight line with each other. In other words, the sidewall 142AS of the lower capping pattern 142A and the sidewall 144AS of the first insulating layer pattern 144A may be coplanar with each other.

A first spacer layer 152 may include a first protrusion PTR1. The first protrusion PTR1 may fill the second recess RS2 and may protrude in a round shape (e.g., in a convex shape) in the first direction X away from the sidewall 152AS, which may cover (e.g., may be in contact with) the sidewalls 142AS, 144AS, and 146AS. The first protrusion PTR1 may cover (e.g., may be in contact with) the first corner portion 144E1 (e.g., the outer surface thereof), the second corner portion 144E2 (e.g., the outer surface thereof), the third corner portion 146E1 (e.g., the outer surface thereof), and the fourth corner portion 146E2 (e.g., the outer surface thereof). The first protrusion PTR1 may cover (e.g., may be in contact with) the sidewall 145AS of the second insulating layer pattern 145A. The first protrusions PTR1 of the first spacer layer 152 may be understood to protrude (e.g., in a round shape) on opposite side surfaces of the insulating capping structure 140 in the first direction X.

Referring to FIG. 4, the second insulation pattern 112B of the isolation layer 112 may include third recesses RS3 (e.g., may include one or more surfaces that define third recesses RS3) that are recessed in a direction opposite to the third direction Z (that is, downward direction). The third direction Z may be referred to herein as a vertical direction extending perpendicular to the upper surface 110S of the substrate 110. The third recesses RS3 may be recessed into (e.g., away from, in the downward direction) the upper surface 110S of the substrate 110. The first insulation pattern 112A may not include a recess (e.g., may not include any recesses in the third direction Z into and/or away from the level of the upper surface 110S of the substrate 110. A vertical level of an upper surface 112Aa of the first insulation pattern 112A may be referred to as a first level LV1. A vertical level of a bottom surface RS3b of the third recess RS3 (which may be referred to herein as an upper surface 112Ba of the second insulation pattern 112B) may be referred to as a second level LV2. The second level LV2 may be lower than the first level LV1. The upper surfaces 112Aa and 112Ba may collectively define an upper surface 112S of the isolation layer 112.

A second portion 144B2 of the protective layer 144B may include a second protrusion PTR2. The second protrusion PTR2 may protrude while filling the third recess RS3. The second protrusion PTR2 may have a downwardly round shape (e.g., convex shape, convex downward in the vertical direction). For example, the second protrusion PTR2 may be rounded downward in the vertical direction (e.g., the third direction Z).

The first interlayer insulating layer 149A may include a third protrusion PTR3. The third protrusion PTR3 may vertically overlap the second protrusion PTR2. The third protrusion PTR3 may be a protrusion that is downwardly round (e.g., is rounded downward in the vertical direction, has a round shape downward in the vertical direction, etc.) like the second protrusion PTR2.

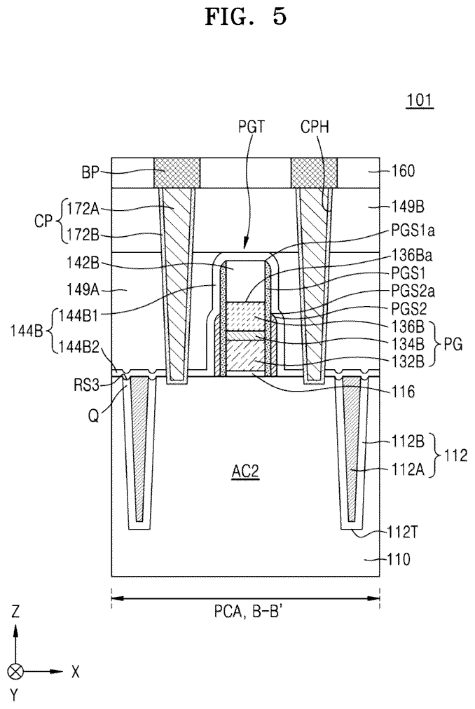

FIG. 5 is a cross-sectional view of an integrated circuit device 101 according to some example embodiments of the inventive concepts, taken along line B-B′ of FIG. 1. The descriptions other than below may overlap the descriptions provided above with reference to FIGS. 1 to 4. Therefore, redundant descriptions are omitted, and differences are described below.

Referring to FIG. 5, a vertical level of the uppermost surface PGS2a of the second insulating spacer PGS2 in the integrated circuit device 101 may be lower than that of the upper surface 136Ba of the upper conductive pattern 136B. A vertical level of the uppermost surface PGS2a of the second insulating spacer PGS2 may be different from that of the upper surface PGS1a of the first insulating spacer PGS1. That is, the uppermost surface PGS2a of the second insulating spacer PGS2 and the upper surface PGS1a of the first insulating spacer PGS1 may have a step therebetween (e.g., the uppermost surface PGS2a of the second insulating spacer PGS2 and the upper surface PGS1a of the first insulating spacer PGS1 may collectively define an upper surface having a step difference in vertical level, which may also be referred to as a discontinuous change in vertical level in the third direction Z corresponding to change in position in the first direction X).

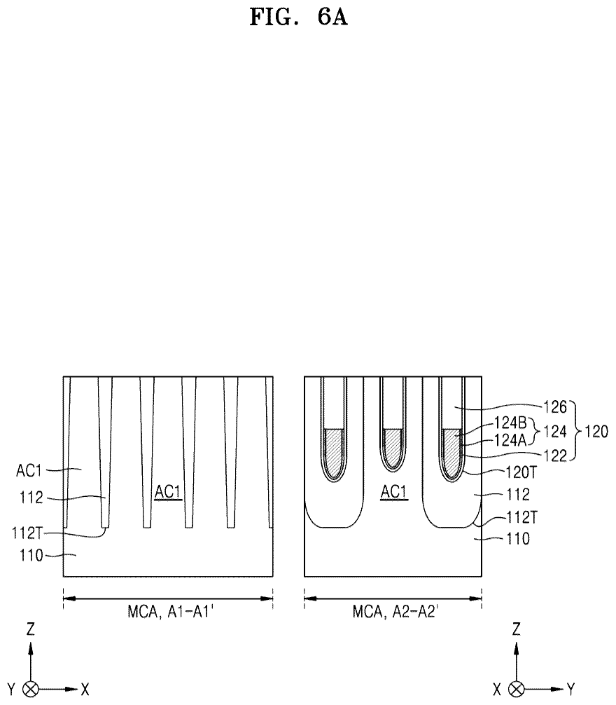

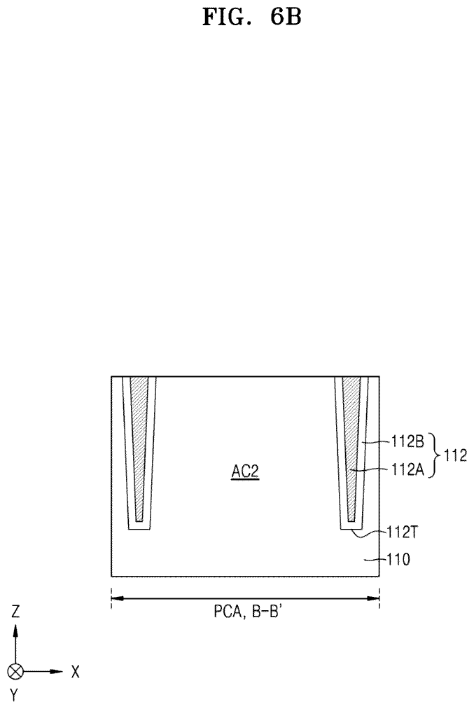

FIGS. 6A, 6B, 7A, 7B, 8A, 8B, 9, 10A, 10B, 11A, 11B, 12, 13, 14, 15, 16, 17, 18, 19A, 19B, 20A, and 20B are cross-sectional views describing a method of manufacturing an integrated circuit device, according to some example embodiments of the inventive concepts, in a processing order. In detail, FIGS. 6A, 7A, 8A, 10A, 11A, 12, 13, 14, 15, 16, 17, 18, 19A, and 20A are cross-sectional views corresponding to the cross-section taken along lines A1-A1′ and A2-A2′ of FIG. 1, and FIGS. 6B, 7B, 8B, 9, 10B, 11B, 19B, and 20B are cross-sectional views corresponding to the cross-section taken along line B-B′ of FIG. 1.

Referring to FIGS. 6A and 6B, the plurality of isolation trenches 112T and the plurality of isolation layers 112 are formed in the substrate 110 having the cell array area MCA and the peripheral circuit area PCA so as to define the plurality of first activation areas AC1 in the cell array area MCA of the substrate 110 and the second activation area AC2 in the peripheral circuit area PCA. Forming of the isolation layers 112 in the peripheral circuit area PCA may include forming a second insulation pattern layer (not shown) covering the sidewalls of the isolation trenches 112T, forming of a first insulation pattern layer (not shown) covering the second insulation pattern layer, and performing a planarization process on the first insulation pattern layer and the second insulation pattern layer until the upper surface of the substrate 110 is exposed. Although not shown in the drawings, forming of the isolation layers 112 in the cell array area MCA may be performed by the same method as that of forming the isolation layer 112 in the peripheral circuit area PCA.

The plurality of word line trenches 120T extending in parallel with each other may be formed in the substrate 110 in the cell array area MCA. After washing the resultant in which the plurality of word line trenches 120T are formed, the plurality of gate dielectric layers 122, the plurality of gate electrode 124, and the plurality of capping insulating layers 126 may be sequentially formed in the plurality of word line trenches 120T. A plurality of source/drain regions (not shown) may be formed on the plurality of first activation areas AC1 by injecting impurity ions into both side portions of the plurality of gate electrodes in the plurality of first activation areas AC1.

The plurality of gate electrodes 124 may each include a work function adjusting layer 124A and an embedded conductive layer 124B on the inner wall of the plurality of word line trenches 120T. For example, the work function adjusting layer 124A and the embedded conductive layer 124B are sequentially formed on the inner wall in each of the plurality of word line trenches 120T, and portions of the work function adjusting layer 124A and the embedded conductive layer 124B, which are on the upper side of the inner wall of the word line trench 120T, are removed by an etch-back process to form the plurality of gate electrodes 124.

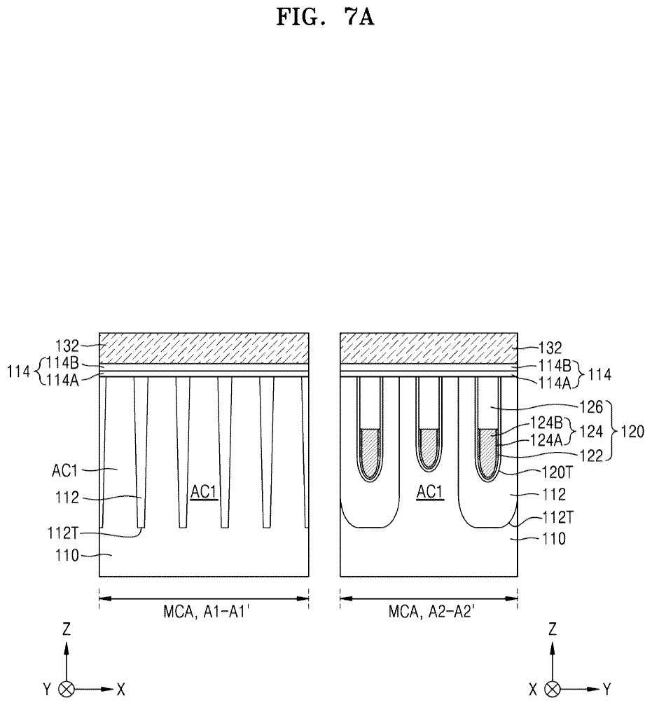

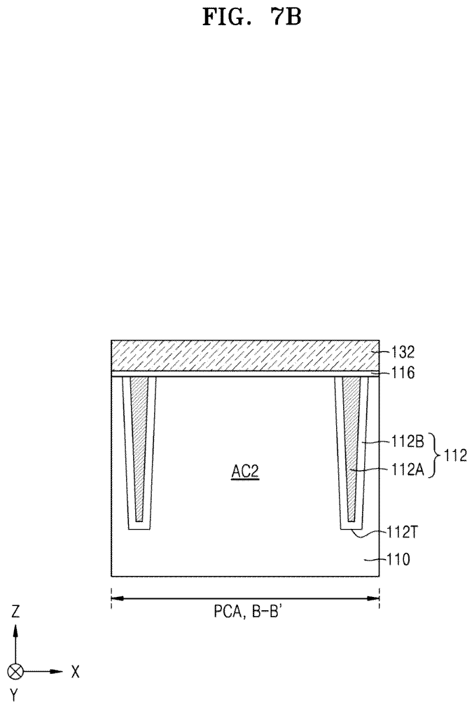

Referring to FIGS. 7A and 7B, the buffer layer 114 including the first insulating layer 114A and the second insulating layer 114B is formed on the substrate 110 in the cell array area MCA, and the gate dielectric layer 116 may be formed on the substrate 110 in the peripheral circuit area PCA.

After that, the lower conductive layer 132 may be formed on the buffer layer 114 in the cell array area MCA and the gate dielectric layer 116 in the peripheral circuit area PCA. In some example embodiments, the lower conductive layer 132 may include Si, Ge, W, WN, Co, Ni, Al, Mo, Ru, Ti, TiN, Ta, TaN, Cu, or any combination thereof. For example, the lower conductive layer 132 may include polysilicon.

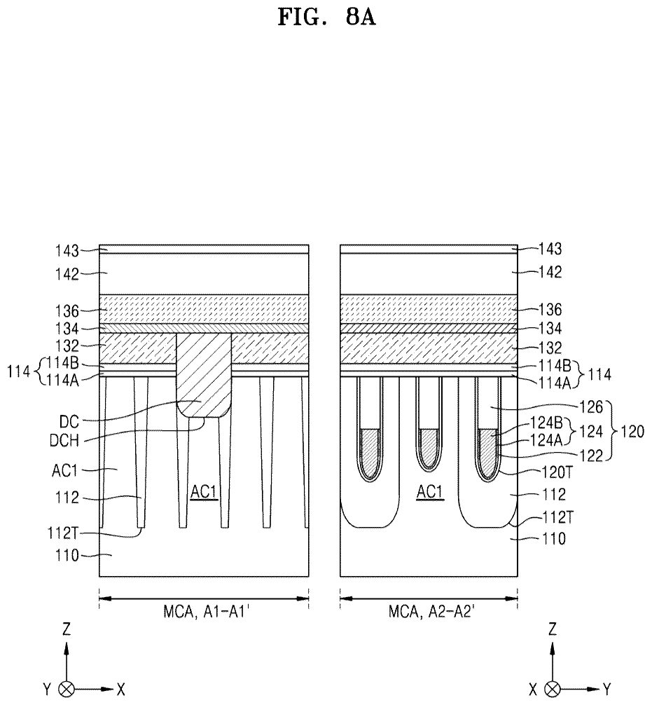

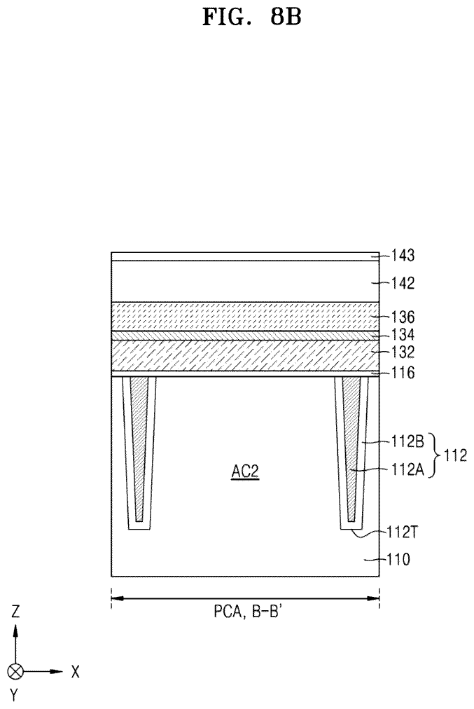

Referring to FIGS. 8A and 8B, a first mask pattern (not shown) is formed on the lower conductive layer 132, and after that, the lower conductive layer 132 exposed through an opening (not shown) of the first mask pattern in the cell array area MCA is etched. Then, parts of the substrate 110 and the isolation layer 112 exposed therefore are etched to form the direct contact hole DCH exposing the first activation areas AC1 of the substrate 110.

After that, the first mask pattern is removed, and the direct contact DC is formed in the direct contact hole DCH. In an exemplary process for forming the direct contact DC, a conductive layer is formed in the direct contact hole DCH and on an upper portion of the lower conductive layer 132 to a thickness that is sufficient enough to fill the direct contact hole DCH, and the conductive layer may be etched-back only to remain in the direct contact hole DCH. The conductive layer may include polysilicon.

After that, in the cell array area MCA and the peripheral circuit area PCA, the intermediate conductive layer 134, the upper conductive layer 136, and the lower capping layer 142 may be sequentially formed on the lower conductive layer and the direct contacts DC. The intermediate conductive layer 134 and the upper conductive layer 136 may each include TIN, TiSiN, W, tungsten silicide, or any combination thereof. The lower capping layer 142 may include a silicon nitride layer.

A first natural insulating layer 143 may be formed on the lower capping layer 142. The first natural insulating layer 143 may be an oxide layer that is naturally generated during the manufacturing processes of the integrated circuit device 100 (e.g., based on oxidation of an exposed upper surface of the lower capping layer 142 due to exposure of the upper surface of the lower capping layer 142 to air). For example, the first natural insulating layer 143 may include a silicon oxynitride layer.

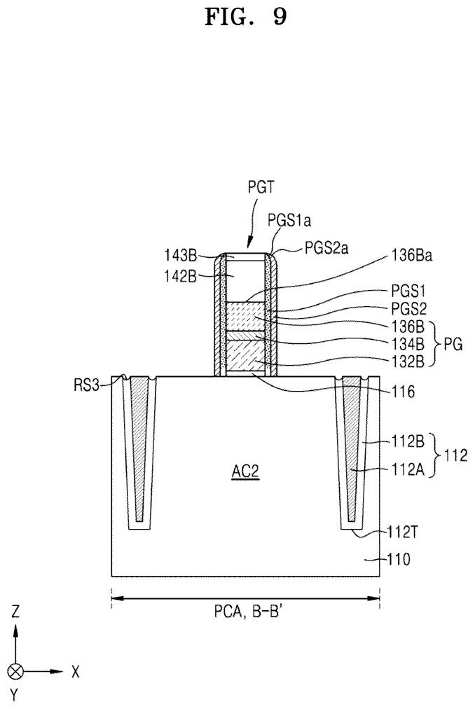

Referring to FIG. 9, while the cell array area MCA is covered by a mask pattern (not shown), the gate dielectric layer 116, the lower conductive layer 132, the intermediate conductive layer 134, the upper conductive layer 136, the lower capping layer 142, and the first natural insulating layer 143 are patterned in the peripheral circuit area PCA, so as to form the gate electrode PG including the lower conductive pattern 132B, the intermediate conductive pattern 134B, and the upper conductive pattern 136B on the gate dielectric layer 116, the gate capping pattern 142B covering the gate electrode PG, and the third insulating layer pattern 143B covering the gate capping pattern 142B. After that, the first insulating spacers PGS1 may be formed on both sidewalls of the gate structure PGT having a stack structure including the gate dielectric layer 116, the gate electrode PG, the gate capping pattern 142B, and the third insulating layer pattern 143B. The second insulating spacer PGS2 may be formed on the first insulating spacer PGS1. Here, a vertical level of the uppermost surface PGS2a of the second insulating spacer PGS2 may be substantially the same as that of the uppermost surface PGS1a of the first insulating spacer PGS1. Also, the vertical level of the uppermost surface PGS2a of the second insulating spacer PGS2 may be higher than that of the upper surface 136Ba of the upper conductive pattern 136B.

An ion implantation process for forming the source/drain regions in the second activation area AC2 may be performed at both sides of the gate structure PGT.

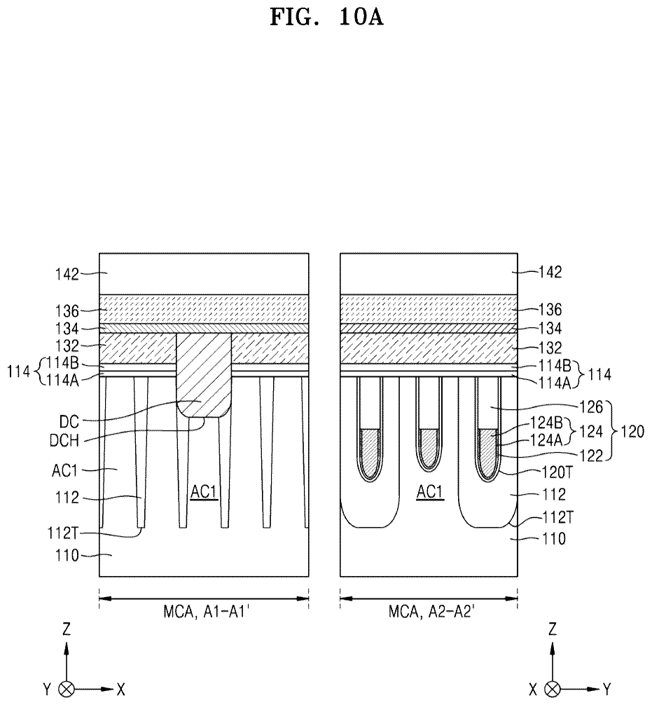

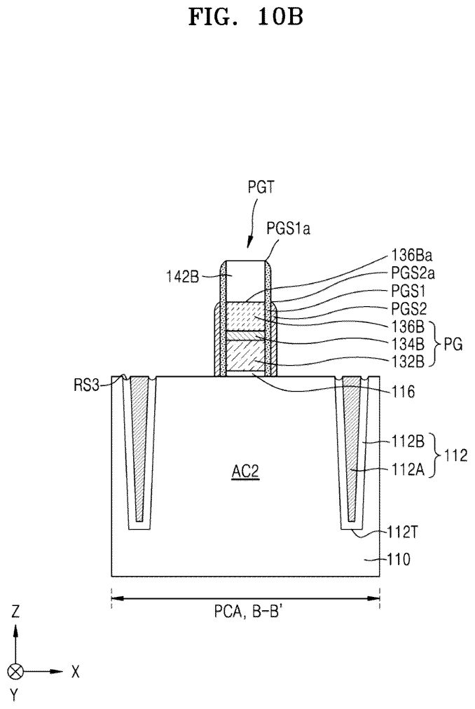

Referring to FIGS. 10A and 10B, the first natural insulating layer 143 and the third insulating layer pattern 143B may be removed. During the removal of the first natural insulating layer 143 and the third insulating layer pattern 143B, the lower capping layer 142 may not be removed. For example, the first natural insulating layer 143 and the third insulating layer pattern 143B may be removed by a strip process using hydrofluoric acid (HF). During the process of removing the first natural insulating layer 143 and the third insulating layer pattern 143B, the first insulating spacer PSG1 and the second insulating spacer PGS2 may be partially removed. The second insulating spacer PGS2 may be removed more than the first insulating spacer PGS1. Here, the vertical level of the uppermost surface PGS2a of the second insulating spacer PGS2 may be lower than that of the uppermost surface PGS1a of the first insulating spacer PGS1. The vertical level of an uppermost surface PGS2a of the second insulating spacer PGS2 may be substantially the same as that of an upper surface 136Ba of the upper conductive pattern 136B.

Also, during the process of removing the first natural insulating layer 143 and the third insulating layer pattern 143B, the isolation layer 112 and the second insulation pattern 112B may be partially removed. When the second insulation pattern 112B is partially removed, the third recess RS3 that is recessed downward may be generated in the upper surface of the second insulation pattern 112B.

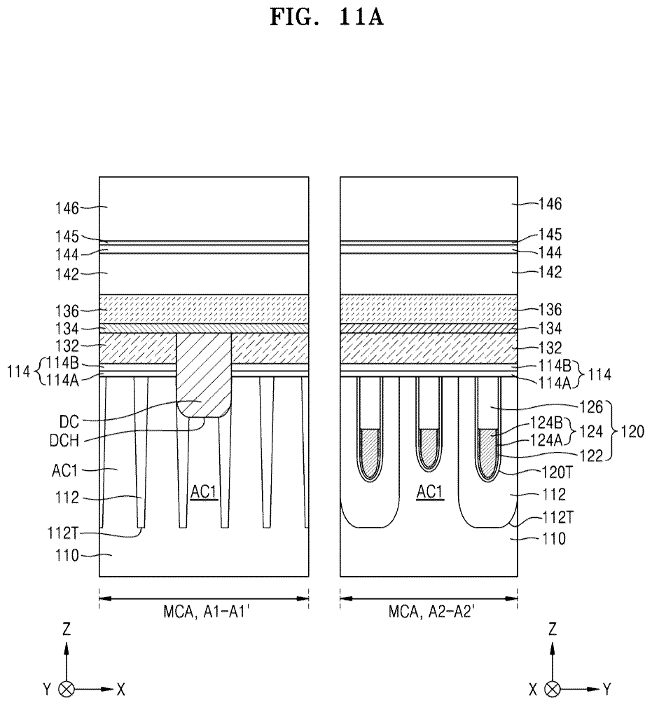

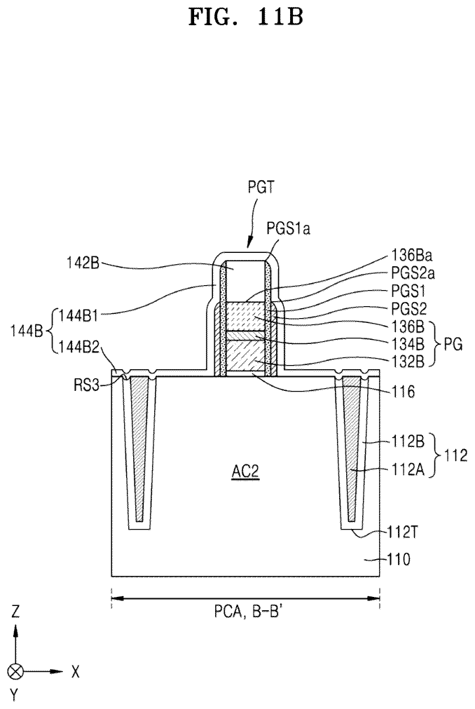

Referring to FIGS. 11A and 11B, the mask pattern covering the cell array area MCA is removed to expose the lower capping layer 142 in the cell array area MCA, and the insulating layer 144 covering the lower capping layer 142 in the cell array area MCA and covering the gate structure PGT, the first insulating spacer PGS1, and the second insulating spacer PGS2 in the peripheral circuit gate structure PGT may be formed. After that, the insulating layer 144 is patterned to form the protective layer 144B in the peripheral circuit area PCA. The protective layer 144B may include the first portion 144B1 covering the gate structure PGT, at least part of the first insulating spacer PGS1, and at least part of the second insulating spacer PGS2, and the second portion 144B2 extending from the first portion 144B1 to the upper surface of the substrate 110.

A mask pattern (not shown) is formed on the peripheral circuit area PCA, and the upper insulating capping layer 146 may be formed on the insulating layer 144 in the cell array area MCA. Before forming the upper insulating capping layer 146, a second natural insulating layer 145 may be formed on the insulating layer 144. The second natural insulating layer 145 may be disposed between the insulating layer 144 and the upper insulating capping layer 146. The second natural insulating layer 145 may be an oxide layer that is naturally generated during the manufacturing processes of the integrated circuit device 100, like the first natural insulating layer 143 shown in FIGS. 8A and 8B. For example, the second natural insulating layer 145 may include a silicon oxynitride layer.

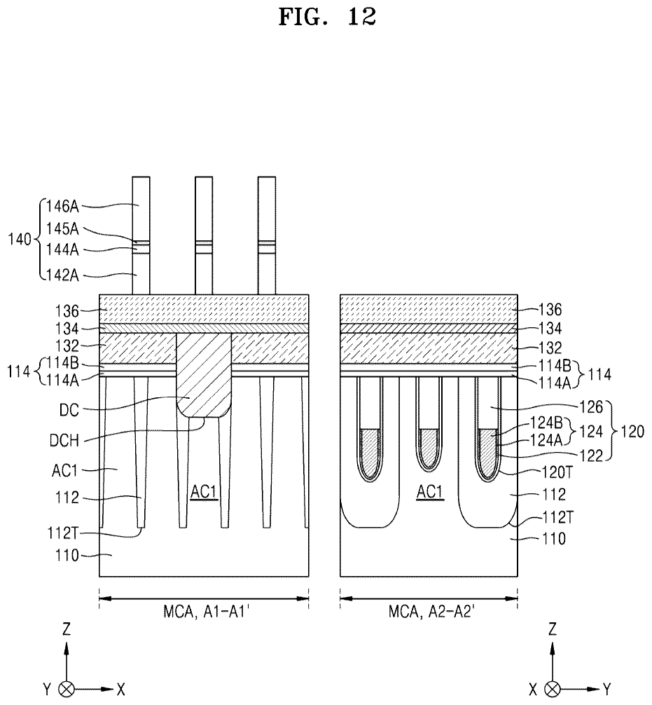

Referring to FIG. 12, in the cell array area MCA, the upper insulating capping layer 146, the second natural insulating layer 145, the insulating layer 144, and the lower capping layer 142 are patterned, and thus, the lower capping pattern 142A, the first insulating layer pattern 144A, the second insulating layer pattern 145A, and the upper capping pattern 146A that are sequentially stacked on the upper conductive layer 136 are formed. Here, the lower capping pattern 142A, the first insulating layer pattern 144A, the second insulating layer pattern 145A, and the upper capping pattern 146A are referred to as an insulating capping structure 140. The insulating capping structure 140 may be formed by a dry etching process.

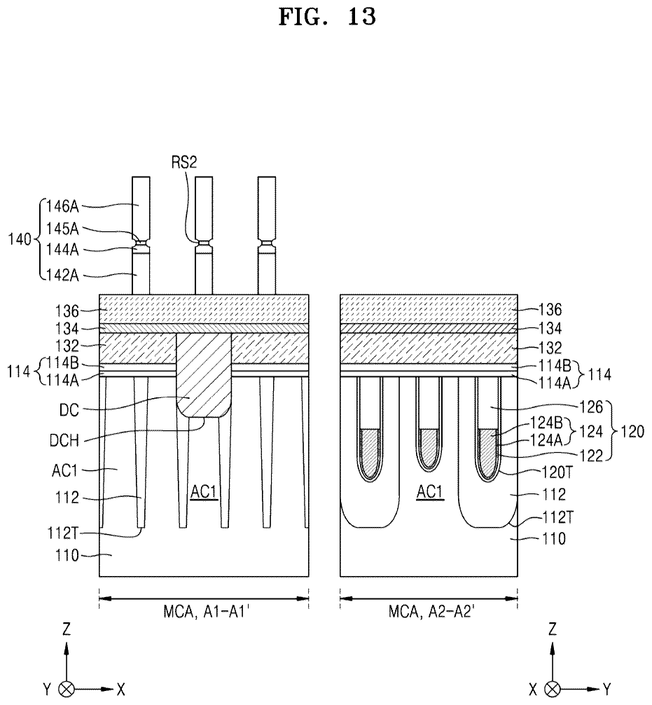

Referring to FIG. 13, after forming the insulating capping structure 140, a strip process or an ashing process for removing by-products may be performed. The second insulating layer pattern 145A is partially etched while performing the strip process or the ashing process, so as to form the second recess RS2. Although not shown in the drawings, while performing the strip process or the ashing process, the first to fourth corner portions 144E1, 144E2, 146E1, and 146E2 shown in FIG. 3 with respect to the first insulating layer pattern 144A and the upper capping pattern 146A may be simultaneously formed. That is, due to the existence of the second insulating layer pattern 145A, the first insulating layer pattern 144A, the second insulating layer pattern 145A, and the upper capping pattern 146A may each have both sides (e.g., opposite sides thereof) recessed in a round shape (e.g., concave shape) in the first direction X during the manufacturing processes of the integrated circuit device 100. In particular, the first insulating layer pattern 144A and the upper capping pattern 146A may have the chamfered shapes described above with reference to FIG. 3.

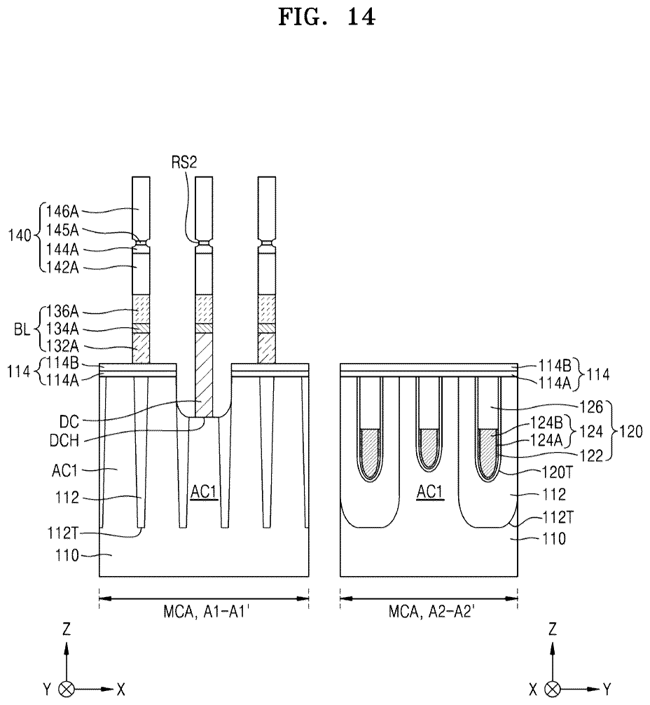

Referring to FIG. 14, in the cell array area MCA, the upper conductive layer 136, the intermediate conductive layer 134, and the lower conductive layer 132 are etched by using the lower capping pattern 142A, the first insulating layer pattern 144A, and the upper capping pattern 146A as an etching mask, and then, the plurality of bit lines BL each including the lower conductive pattern 132A, the intermediate conductive pattern 134A, and the upper conductive pattern 136A are formed.

During the processes of forming the plurality of bit lines BL, the sidewall of the direct contact DC is partially removed and the direct contact hole DCH may be partially exposed.

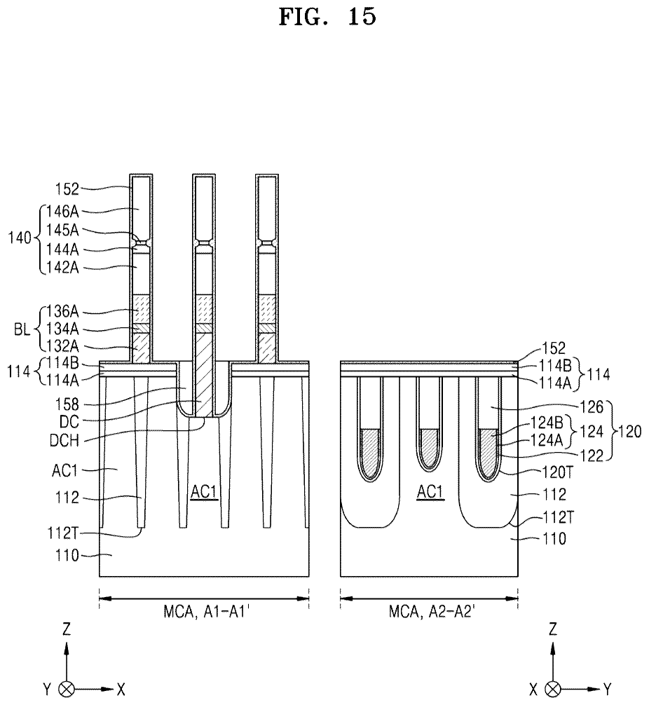

Referring to FIG. 15, the first spacer layers 152 may be formed on the sidewalls of the plurality of bit lines BL and the sidewalls of the direct contacts DC. Although not shown in FIG. 15, the first spacer layer 152 may include the protrusion filled in the second recess RS2 shown in FIG. 13. The protrusion of the first spacer layer 152 may be the same as the first protrusion PTR1 of the first spacer layer 152 shown in FIG. 3. After that, an insulating layer (not shown) is formed to a thickness that is enough to fill the direct contact hole DCH is formed on the sidewalls of the plurality of bit lines BL and the sidewalls of the direct contacts DC, and then, an anisotropic etching process is performed on the insulating layer to remain the embedded insulation layer 158 filled in the direct contact hole DCH.

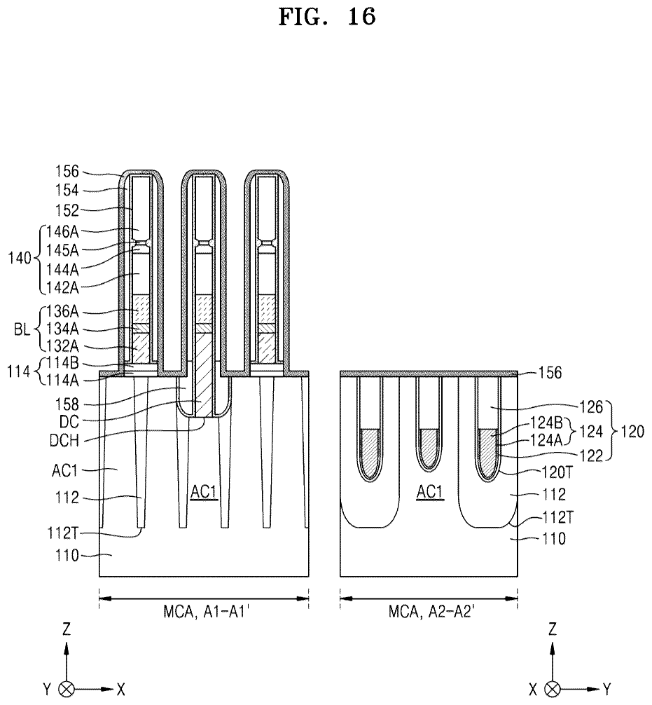

Referring to FIG. 16, the second spacer layers 154 covering the first spacer layers 152 may be formed on the sidewalls of the plurality of bit lines BL. Parts of the buffer layer 114 disposed among the plurality of bit lines BL are removed by using the second spacer layer 154 as an etching mask to expose the upper surface of the substrate 110. Here, the embedded insulation layer 158 may also be partially removed.

After that, the third spacer layers 156 may be formed on the sidewalls of the plurality of bit lines BL and the upper surface of the substrate 110.

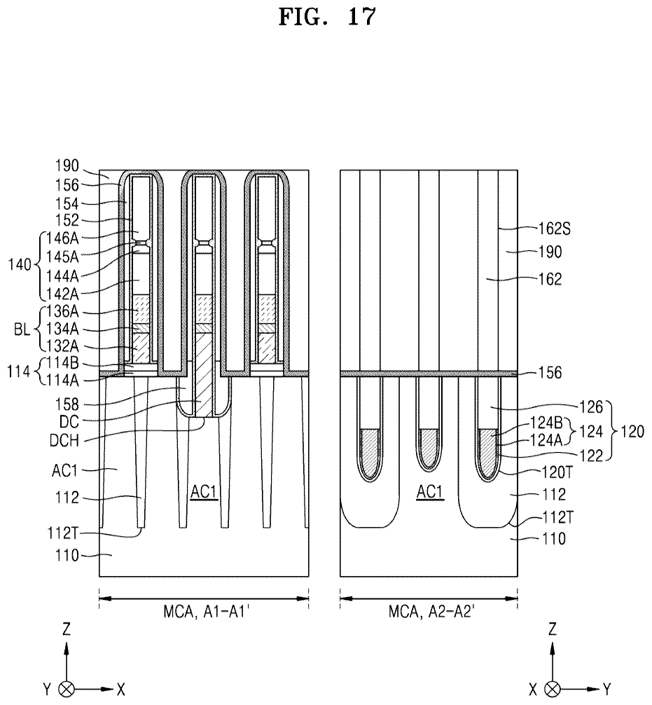

Referring to FIG. 17, in the cell array area MCA, the plurality of insulating fences 162 may be formed between the plurality of bit lines BL. For example, the plurality of insulating fences 162 may be formed to vertically overlap the plurality of word line trenches 120T, and upper surfaces of the plurality of insulating fences 162 may be located at the same level as the upper surface of the third spacer layer 156.

The plurality of insulating fences 162 may be arranged to be spaced apart from one another in the second direction Y, and accordingly, contact spaces 162S may be defined between two adjacent insulating fences 162 from among the plurality of insulating fences 162 and between two bit lines BL.

After that, the contact space 162S between the insulating fences 162 is filled with an insulating material, and an upper portion of the insulating material is planarized to form an embedded layer 190 in the contact space 162S. For example, the embedded layer 190 may include silicon oxide.

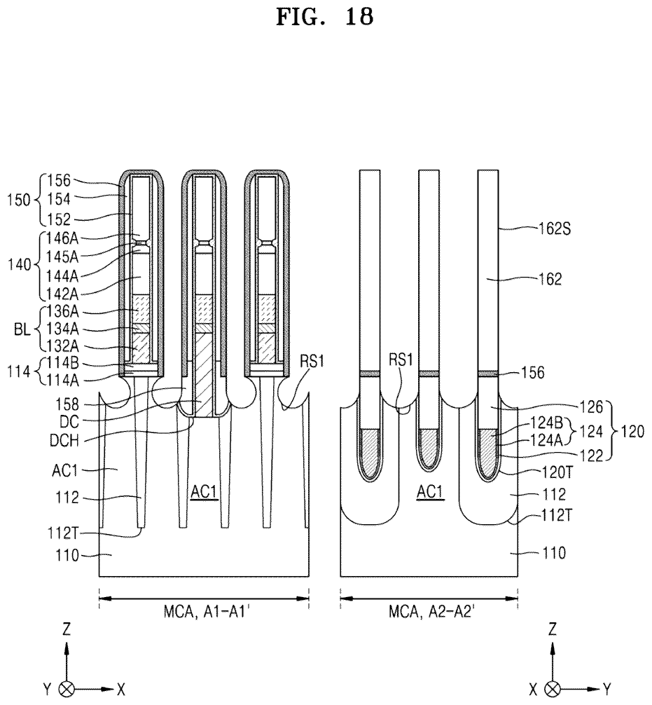

Referring to FIG. 18, the plurality of contact spaces 162S are exposed by removing the embedded layer 190, and the buffer layer 114 disposed on the bottom in each of the plurality of contact spaces 162S and part of the substrate 110 are removed to form the plurality of first recesses RS1 exposing the first activation areas AC1 of the substrate 110 among the plurality of bit lines BL.

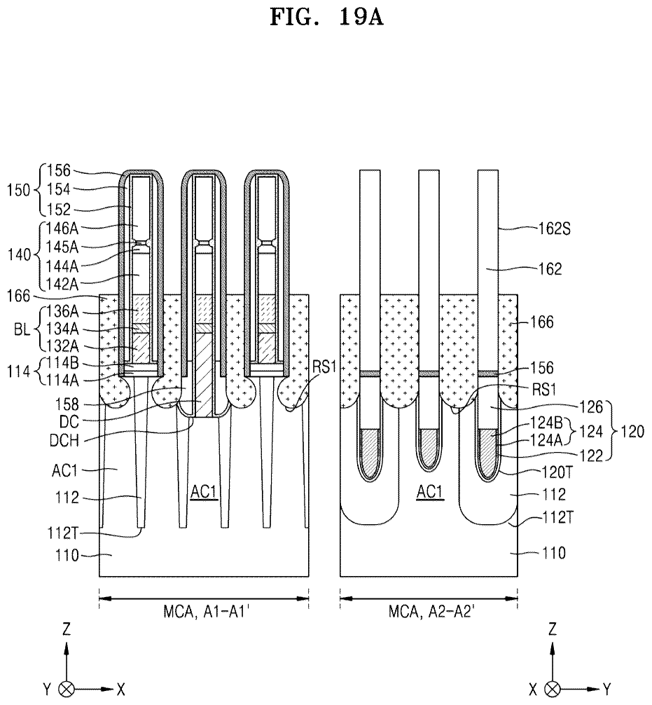

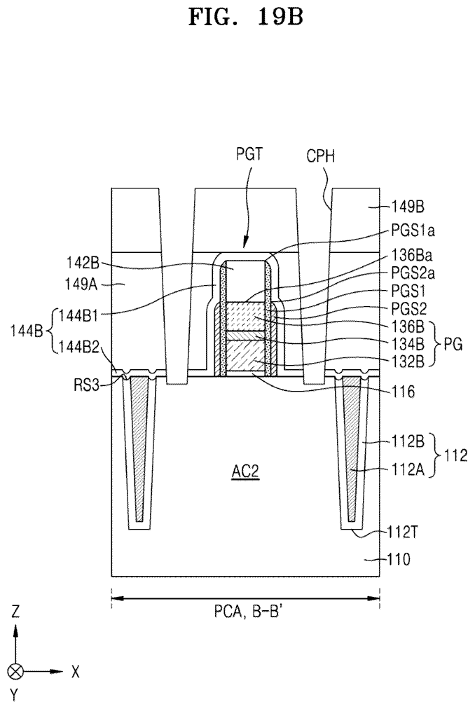

Referring to FIGS. 19A and 19B, in the peripheral circuit area PCA, the first interlayer insulating layer 149A filling the space around the gate structure PGT may be formed. The second interlayer insulating layer 149B may be formed on the first interlayer insulating layer 149A. After that, the second interlayer insulating layer 149B, the first interlayer insulating layer 149A, and the protective layer 144B are etched to form a plurality of contact holes CPH.

In the cell array area MCA, a plurality of conductive plugs 166 that fill some parts of the contact spaces 162S between the plurality of bit lines BL while filling the plurality of first recesses RS1 between the plurality of bit lines BL.

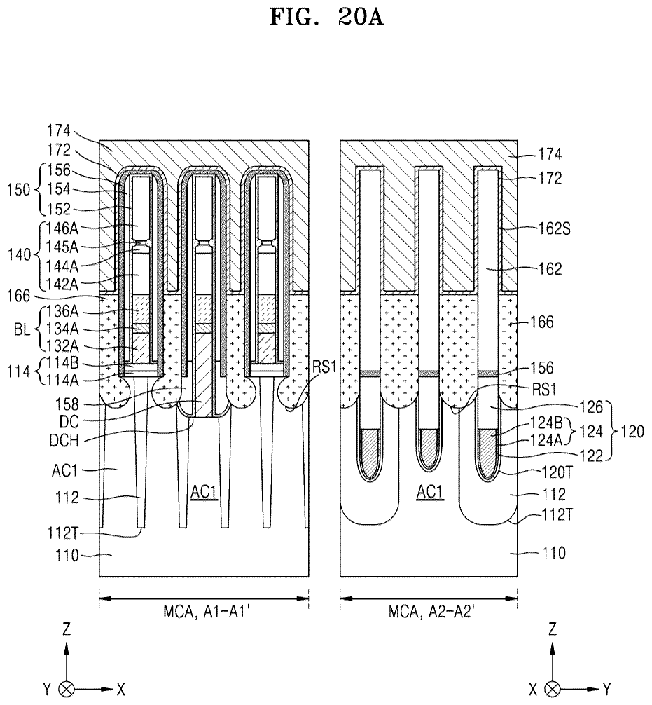

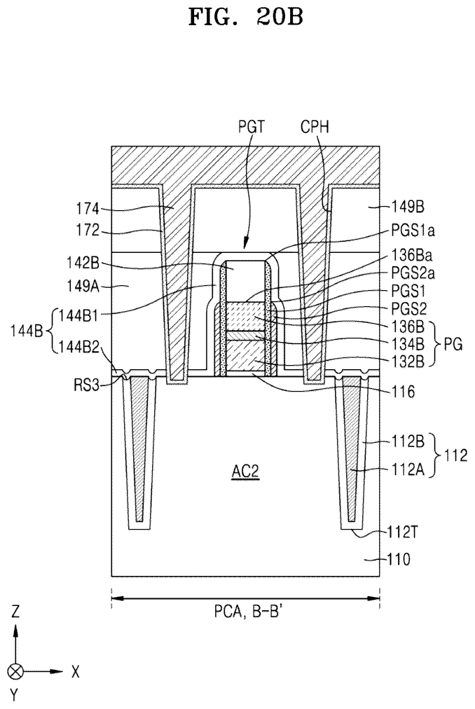

Referring to FIGS. 20A and 20B, in the cell array area MCA and the peripheral circuit area PCA, the conductive barrier layer 172 and the conductive layer 174 covering the exposed surfaces of the substrate 110 may be formed. Although not shown in the drawings, before forming the conductive barrier layer 172 and the conductive layer 174, a metal silicide layer (not shown) may be formed on the conductive plugs 166 exposed through the plurality of contact spaces 162S, and a metal silicide layer (not shown) may be formed on the surface of the second activation area AC2 exposed through the plurality of contact holes CPH in the peripheral circuit area PCA. The metal silicide layers may be simultaneously formed or may be formed through separate processes.

Referring back to FIGS. 2A and 2B, in the cell array area MCA and the peripheral circuit area PCA, the conductive layer 174 and the conductive barrier layer 172 are patterned to form the plurality of landing pads LP each including the conductive barrier layer 172A and the landing pad conductive layer 174A in the cell array area MCA, and to form the plurality of contact plugs CP each including the conductive barrier layer 172B and the landing pad conductive layer 174B in the peripheral circuit area PCA. The plurality of landing pads LP may have island-type pattern shape on a plane, as shown in FIG. 1. The plurality of landing pads LP may be formed to vertically overlap some of the plurality of bit lines BL in the vertical direction (e.g., the third direction Z).

After that, in the cell array area MCA, an insulating pattern 180 may be formed on the inner wall of the insulating space 180S by using an insulating material. The insulating pattern 180 may be formed by a spin coating process, a chemical vapor deposition (CVD) process, a flowable CVD process, etc. After that, in the cell array area MCA, a capacitor lower electrode (not shown) may be formed on the plurality of landing pads LP.

The third interlayer insulating layer 160 may be formed on the peripheral circuit area PCA. After that, the metal wirings BP penetrating through the third interlayer insulating layer 160 and coming into contact with the contact plugs CP may be formed.

The integrated circuit device 100 according to some example embodiments is completed according to the above-described manufacturing method.

According to the above manufacturing method, the first natural insulating layer 143 that is naturally generated while forming the lower capping layer 142 may be removed by a strip process. As such, in the strip process or the ashing process performed after patterning the insulating capping structure 140 and the bit lines BL, recesses may not be formed in the boundary surface between the lower capping pattern 142A and the first insulating layer pattern 144A. For at least the above reasons, the bending effect in which the insulating capping structure 140 and the bit lines BL are bent may be reduced, minimized, or prevented, and thus, the electrical characteristics and reliability of the integrated circuit device 100 may be improved.

While the inventive concepts have been particularly shown and described with reference to some example embodiments thereof, it will be understood that various changes in form and details may be made therein without departing from the spirit and scope of the following claims.

What is claimed is:

1. An integrated circuit device, comprising:
a substrate including a cell array area and a peripheral circuit area next to the cell array area;
an isolation layer defining an activation region of the substrate in the peripheral circuit area, the isolation layer including a first insulation pattern and a second insulation pattern, the second insulation pattern surrounding the first insulation pattern; and
a gate structure on the substrate in the peripheral circuit area,
wherein the second insulation pattern includes one or more surfaces defining a recess into an upper surface of the substrate in a vertical direction, the vertical direction extending perpendicular to the upper surface of the substrate.

2. The integrated circuit device of claim 1, further comprising a protective layer covering the gate structure and an upper surface of the isolation layer,
wherein the protective layer includes a first protrusion filling the recess of the second insulation pattern and is rounded downward in the vertical direction.

3. The integrated circuit device of claim 2, further comprising:
an interlayer insulating layer at least partially covering the protective layer,
the interlayer insulating layer includes a second protrusion protruding in the vertical direction from a portion vertically overlapping the recess, and
the second protrusion is rounded downward in the vertical direction.

4. The integrated circuit device of claim 1, wherein the second insulation pattern includes a material having etch selectivity with respect to the first insulation pattern.

5. The integrated circuit device of claim 4, wherein
a vertical level of an upper surface of the first insulation pattern is a first level,
a vertical level of a bottom surface of the recess is a second level, and
the second level is lower than the first level.

6. The integrated circuit device of claim 1, further comprising
a bit line on the substrate and an insulating capping structure on the bit line in the cell array area,
wherein the bit line and the insulating capping structure extend in a first horizontal direction parallel to the upper surface of the substrate,
the insulating capping structure includes a lower capping pattern, an upper capping pattern on the lower capping pattern, and a first insulating layer pattern between the lower capping pattern and the upper capping pattern, and
the first insulating layer pattern and the upper capping pattern each have a chamfered shape wherein respective opposite sides of each of the first insulating layer pattern and the upper capping pattern are recessed to be round in a second horizontal direction crossing the first horizontal direction and parallel to the upper surface of the substrate.

7. The integrated circuit device of claim 6, further comprising spacer layers covering opposite side surfaces of the insulating capping structure,
wherein the spacer layers have protrusions each protruding in a round shape on the opposite sides of the insulating capping structure in the second horizontal direction.

8. The integrated circuit device of claim 6, wherein a sidewall of the lower capping pattern and a sidewall of the first insulating layer pattern are coplanar with respect to each other.

9. The integrated circuit device of claim 6, further comprising a second insulating layer pattern between the first insulating layer pattern and the upper capping pattern,
wherein the second insulating layer pattern includes a silicon oxynitride layer.

10. The integrated circuit device of claim 6, further comprising a protective layer covering the gate structure and an upper surface of the isolation layer,
wherein the first insulating layer pattern and the protective layer include a same material.

11. The integrated circuit device of claim 1, further comprising:
an insulating spacer on a side surface of the gate structure,
wherein the gate structure includes a peripheral circuit gate electrode and a gate capping pattern on the peripheral circuit gate electrode, and
a vertical level of an upper surface of the insulating spacer and a vertical level of an upper surface of the gate capping pattern are different from each other.

12. The integrated circuit device of claim 11, wherein the insulating spacer is spaced apart in a horizontal direction from the gate structure and the upper surface of the substrate, the horizontal direction extending parallel to the upper surface of the substrate.

13. An integrated circuit device comprising:
a substrate including a cell array area and a peripheral circuit area next to the cell array area;
an isolation layer defining an activation area of the substrate;
a peripheral circuit gate structure on the substrate in the peripheral circuit area;
a first insulating spacer at least partially covering a sidewall of the peripheral circuit gate structure; and
a second insulating spacer at least partially covering a sidewall of the first insulating spacer,
wherein a vertical level of an upper surface of the second insulating spacer is lower than a vertical level of an upper surface of the first insulating spacer.

14. The integrated circuit device of claim 13, wherein the second insulating spacer includes a material having etch selectivity with respect to the first insulating spacer.

15. The integrated circuit device of claim 13, wherein
the peripheral circuit gate structure includes a peripheral circuit gate electrode and a gate capping pattern on the peripheral circuit gate electrode, and
an upper surface of the second insulating spacer and an upper surface of the peripheral circuit gate electrode collectively define an upper surface having a step difference in vertical level.

16. The integrated circuit device of claim 13, further comprising:
a bit line on the substrate and an insulating capping structure on the bit line, in the cell array area,
wherein the bit line and the insulating capping structure extend in parallel to an upper surface of the substrate,
wherein the insulating capping structure includes a lower capping pattern, an upper capping pattern on the lower capping pattern, and a first insulating layer pattern between the lower capping pattern and the upper capping pattern, and
wherein the second insulating spacer includes a material having etch selectivity with respect to the lower capping pattern.

17. The integrated circuit device of claim 16, wherein the first insulating spacer includes a material that is a same material as a material in the lower capping pattern.

18. The integrated circuit device of claim 17, wherein
the isolation layer includes a first insulation pattern and a second insulation pattern surrounding the first insulation pattern, and
the second insulation pattern and the second insulating spacer include a same material.

19. An integrated circuit device, comprising:
a substrate including a cell array area and a peripheral circuit area next to the cell array area;
an isolation layer defining an activation area of the substrate;
a plurality of bit lines extending on the substrate in a first direction in the cell array area, the first direction parallel to an upper surface of the substrate;
a plurality of insulating capping structures on separate, respective bit lines of the plurality of bit lines and extending in the first direction;
a conductive plug between two adjacent bit lines from among the plurality of bit lines;
a landing pad on the conductive plug; and
a gate structure on the substrate in the peripheral circuit area,
wherein each of the plurality of insulating capping structures includes a separate sequential stack of a lower capping pattern, a first insulating layer pattern, a second insulating layer pattern, and an upper capping pattern, each separate sequential stack on a separate bit line of the plurality of bit lines,
wherein a width of the second insulating layer pattern in a second direction is less than a width in the second direction of at least one of the lower capping pattern, the first insulating layer pattern, and the upper capping pattern, and
wherein the second direction is parallel to the upper surface of the substrate and perpendicular to the first direction.

20. The integrated circuit device of claim 19, wherein a material in the second insulating layer pattern is different from materials included in the lower capping pattern, the first insulating layer pattern, and the upper capping pattern.
